(19) United States
(12) Patent Application Publication
(10) Pub. No.: US 2001/0019179 A1
(43) Pub. Date: Sep. 6, 2001

(54) Connecting method of semiconductor element and semiconductor device

(76) Inventors: Yoshitaka Yoshino, Tokyo (JP); Hirokazu Nakayoshi, Kanagawa (JP)

Correspondence Address: RADER FISHMAN & GRAUER PLLC, LION BUILDING, 1233 20TH STREET N.W., SUITE 501, WASHINGTON, DC, 20036, US

(21) Appl. No.: 09/747,934

(22) Filed: Dec. 27, 2000

(30) Foreign Application Priority Data
Dec. 28, 1999 (JP) P11-374650

(51) Int. Cl. H01L 23/52; H01L 23/053; H01L 23/12; H01L 23/48; H01L 29/40

(52) U.S. Cl. 257/784; 257/691; 257/700

(57) ABSTRACT

There is provided a connection method of a semiconductor element in which even in the case where a semiconductor element includes a sealing inhibited region, it can be easily electrically connected to a substrate, and thinning and miniaturization can be realized. In the connecting method of the semiconductor element for electrically connecting the semiconductor element to the substrate, an electrical connection sheet for enabling electrical connection between the semiconductor element and the substrate is disposed on the substrate, a punched hole is formed by punching a region of the substrate corresponding to a sealing inhibited region of the semiconductor element which is a region where a function of the semiconductor element is performed and sealing is inhibited, together with the electrical connection sheet, the semiconductor element is disposed on the substrate through the electrical connection sheet, and electrodes located at a remainder portion except the sealing inhibited region of the semiconductor element is electrically connected to electrodes of the substrate.

### BACKGROUND OF THE INVENTION

1. Field of the Invention

The present invention relates to a connecting method of a semiconductor element and a semiconductor device.

2. Description of the Related Art

Conventionally, as mounting forms of a semiconductor element, there are adopted an electrical connecting method in which an element is put upward on a circuit substrate and wiring is made by an Au wire, and a flip chip mounting method in which a projection electrode is formed on a semiconductor element and the electrode of the semiconductor element is directly connected to a power source of a circuit substrate.

The former method has a problem that thickening and enlarging are caused by the size of the wire, although a countermeasure can be taken, and thinning and miniaturization are prevented. In the case of mounting of a semiconductor element requiring a sealing inhibited region at its center, in the latter flip chip mounting, since sealing of a connection portion is necessary in view of reliability, soldering connection is difficult, and even in the case where an anisotropic conductive sheet or resin sheet is used, such a method has been considered that only a portion of an unsealed region of the sheet is cut out by a pair of scissors, the sheet is bonded to a circuit substrate, and then, mounting is made. However, in the case where the semiconductor element is small, such a measure is difficult, and position accuracy at the time of bonding to the circuit substrate is also problematic.

### SUMMARY OF THE INVENTION

The present invention has been made to solve the above problems and an object of the present invention is to provide a connecting method of a semiconductor element in which even in a case where a semiconductor element includes a sealing inhibited region, it can be easily electrically connected to a substrate, and thinning and miniaturization can be realized, and is to provide a semiconductor device.

According to a first aspect of the invention, a connecting method of a semiconductor element, for electrically connecting a semiconductor element to a substrate, includes the steps of disposing an electrical connection sheet on the substrate, for enabling electrical connection between the semiconductor element and the substrate, forming a punched hole by punching a region of the substrate corresponding to a sealing inhibited region of the semiconductor element which is a region where a function of the semiconductor element is performed and sealing is inhibited, together with the electrical connection sheet, disposing the semiconductor element on the substrate through the electrical connection sheet, and electrically connecting an electrode located at the remainder portion except the sealing inhibited region of the semiconductor element to an electrode of the substrate.

In the first aspect, the electrical connection sheet enabling the electrical connection between the semiconductor element and the substrate is disposed on the substrate. The region of the substrate corresponding to the sealing inhibited region which is the region where the function of the semiconductor element is performed, together with the electrical connection sheet, is punched to form the punched hole.

The semiconductor element is disposed on the substrate through the electrical connection sheet, and the electrode located at the remainder portion except the sealing inhibited region of the semiconductor element is electrically connected to the electrode of the substrate.

By doing so, the semiconductor element including the sealing inhibited region can be made open to the outside through the punched hole. Further, since both of the electrical connection sheet and the region of the substrate corresponding to the sealing inhibited region are punched, the punched hole corresponding to the sealing inhibited region can be easily formed. Since the electrode located at the remainder portion except the sealing inhibited region of the semiconductor element is electrically connected to the electrode of the substrate through the electrical connection sheet, miniaturization and thinning of a semiconductor device constituted by the semiconductor, the substrate, and the like can be realized.

According to a second aspect of the invention, in the connecting method of the semiconductor element according to the first aspect, the semiconductor element is a piezoelectric element or a charge coupled element.

According to a third aspect of the invention, in the connecting method of the semiconductor element according to the first aspect, the electrode of the substrate is connected to the projection electrode of the semiconductor element through the electrical connection sheet.

According to a fourth aspect of the invention, in the connecting method of the semiconductor element according to the third aspect, the electrical connection sheet is made of a plurality of conductive particles and an electrical insulator containing the conductive particles.

In the fourth aspect, when the semiconductor element is, for example, pressed to a substrate side through the electrical connection sheet, the plurality of conductive particles in the electrical insulator can electrically connect the electrode located at the remainder portion except the sealing inhibited region of the semiconductor element to the electrode of the substrate.

According to a fifth aspect of the invention, in the connecting method of the semiconductor element according to the first aspect, the substrate is a printed wiring substrate or a flexible wiring substrate.

According to a sixth aspect of the invention, in the connecting method of the semiconductor element according to the first aspect, the electrical connection sheet and the region of the substrate corresponding to the sealing inhibited region are punched simultaneously and from an electrical connection sheet side to form the punched hole.

In the sixth aspect, when the punched hole is formed, punching is made from the electrical connection sheet side, so that resin making the electrical connection sheet protrudes to the opposite side of the mounting surface of the semiconductor element, and therefore, at the time of mounting of the semiconductor element, it becomes possible to make adhesion to the surface of the semiconductor element minimum.

According to a seventh aspect of the invention, in the connecting method of the semiconductor element according to the first aspect, an adhesion preventing member is disposed to prevent a part of the electrical connection sheet from protruding through the punched hole to an opposite side of the substrate and adhering when the semiconductor element is disposed on the substrate through the electrical connection sheet, and the electrode located at the remainder portion except the sealing inhibited region of the semiconductor element is electrically connected to the electrode of the substrate.

In the seventh aspect, by disposing the adhesion preventing member, even in the case where connection of the semiconductor element is performed, for example, in the state where the substrate is put on a table, it is possible to prevent the part of the electrical connection sheet from protruding to the opposite side of the substrate and adhering to, for example, a table side.

According to an eighth aspect of the invention, in the connecting method of the semiconductor element according to the first aspect, in the case where the substrate is the flexible wiring substrate, the substrate is a two-layer substrate.

In the eighth aspect, by using the two-layer flexible wiring substrate, as compared with the use of, for example, a three-layer flexible wiring substrate, an inner diameter of the punched hole can be easily secured, and protrusion of an adhesive layer of the flexible wiring substrate is prevented.

According to a ninth aspect of the invention, a semiconductor device comprises a semiconductor element including a sealing inhibited region which is a region where a function is performed and sealing is inhibited, a substrate, and an electrical connection sheet disposed on the substrate and enabling electrical connection between the semiconductor element and the substrate, a punched hole being formed in the electrical connection sheet by punching it together with a region of the substrate corresponding to the sealing inhibited region of the semiconductor element, wherein the semiconductor element is disposed on the substrate through the electrical connection sheet, and an electrode located at a remainder portion except the sealing inhibited region of the semiconductor element is electrically connected to an electrode of the substrate.

In the ninth aspect, the electrical connection sheet enabling the electrical connection between the semiconductor element and the substrate is disposed on the substrate. The region of the substrate corresponding to the sealing inhibited region which is the region where the function of the semiconductor element is performed, together with the electrical connection sheet, is punched to form the punched hole.

The semiconductor element is disposed on the substrate through the electrical connection sheet, and the electrode located at the remainder portion except the sealing inhibited region of the semiconductor element is electrically connected to the electrode of the substrate.

By doing so, the semiconductor element including the sealing inhibited region can be made open to the outside through the punched hole. Further, since both of the electrical connection sheet and the region of the substrate corresponding to the sealing inhibited region are punched, the punched hole corresponding to the sealing inhibited region can be easily formed. Since the electrode located at the remainder portion except the sealing inhibited region of the semiconductor element is electrically connected to the electrode of the substrate through the electrical connection sheet, miniaturization and thinning of the semiconductor device constituted by the semiconductor, the substrate, and the like can be realized.

According to a tenth aspect of the invention, in the semiconductor device according to the ninth aspect, the semiconductor element is a piezoelectric element or a charge coupled element.

According to an eleventh aspect of the invention, in the semiconductor device according to the ninth aspect, the electrode of the substrate is connected to the projection electrode of the semiconductor element through the electrical connection sheet.

According to a twelfth aspect of the invention, in the semiconductor device according to the ninth aspect, the electrical connection sheet is made of a plurality of conductive particles and an electrical insulator containing the conductive particles.

In the twelfth aspect, when the semiconductor element is, for example, pressed to a substrate side through the electrical connection sheet, the plurality of conductive particles in the electrical insulator can electrically connect the electrode located at the remainder portion except the sealing inhibited region of the semiconductor element to the electrode of the substrate.

According to a thirteenth aspect of the invention, in the semiconductor device according to the ninth aspect, the substrate is a printed wiring substrate or a flexible wiring substrate.

According to a fourteenth aspect of the invention, in the semiconductor device according to the ninth aspect, the electrical connection sheet and the region of the substrate corresponding to the sealing inhibited region are punched simultaneously and from an electrical connection sheet side to form the punched hole.

In the fourteenth aspect, when the punched hole is formed, punching is made from the electrical connection sheet side, so that resin making the electrical connection sheet protrudes to the opposite side of the mounting surface of the semiconductor element, and therefore, at the time of mounting of the semiconductor element, it becomes possible to make adhesion to the surface of the semiconductor element minimum.

### BRIEF DESCRIPTION OF THE DRAWINGS

FIG. 1 is a sectional view showing a preferred embodiment of a semiconductor device of the present invention.

FIGS. 2A and 2B are views showing an example of a semiconductor element of the semiconductor device.

FIG. 3 is a view showing an example in which a circuit substrate for constituting the semiconductor device is disposed on a stage.

FIG. 4 is a view showing an example in which an anisotropic conductive film as an anisotropic electrical connection sheet is disposed on the circuit substrate of FIG. 3.

FIG. 5 is a view showing the state before a punched hole is formed in the anisotropic conductive film and the circuit substrate.

FIG. 6 is a view showing the state where the punched hole is formed in the anisotropic conductive film and the circuit substrate.

FIG. 7 is a view showing the state immediately before the semiconductor element is subjected to thermo compression bonding to the circuit substrate through the anisotropic conductive film.

FIGS. 8A and 8B are views showing the state where the semiconductor element has been subjected to the thermo compression bonding to the circuit substrate through the anisotropic conductive film.

FIG. 9 is a view showing a structural example of the anisotropic conductive film as an electrical connection sheet.

FIG. 10 is a view showing the state where a projection electrode of the semiconductor element is electrically connected to a wiring electrode of the circuit substrate through conductive particles of the anisotropic conductive film.

FIG. 11 is a view showing an example of a case where the circuit substrate is of a two-layer type.

FIG. 12 is a view showing an example of a case where the circuit substrate is of a three-layer type.

FIGS. 13A and 13B are views showing an example of the semiconductor element.

### DETAILED DESCRIPTION OF THE PREFERRED EMBODIMENTS

Preferred embodiments of the present invention will be described below with reference to the accompanying drawings.

Incidentally, since the embodiments described below are preferred specific examples of the present invention, technically preferred various limitations are added. However, the scope of the invention is not limited to these embodiments as long as the following description does not contain recitation to specifically limit the invention.

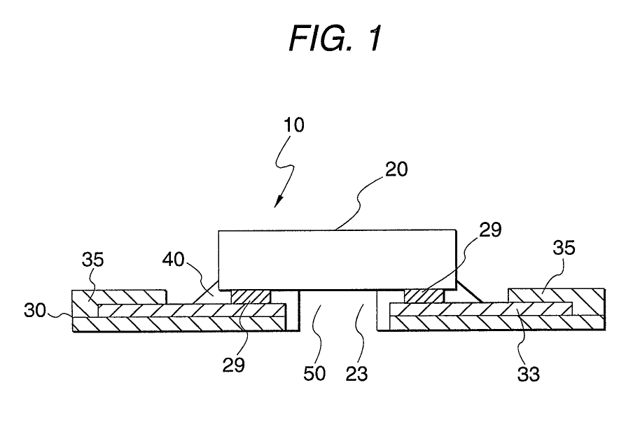

FIG. 1 shows a preferred embodiment of a semiconductor device of the present invention. This semiconductor device 10 roughly includes a semiconductor element 20, a circuit substrate 30 corresponding to a substrate, and an anisotropic conductive film (ACF; Anisotropic Conductive Film) 40 as an electrical connection sheet.

The circuit substrate 30 is, for example, a flexible wiring substrate of two-layer structure. The circuit substrate 30 includes a wiring electrode 33, and a solder resist 35 is provided at a necessary portion. In an example of FIG. 1, the solder resist 35 is positioned at the periphery of the semiconductor element 20.

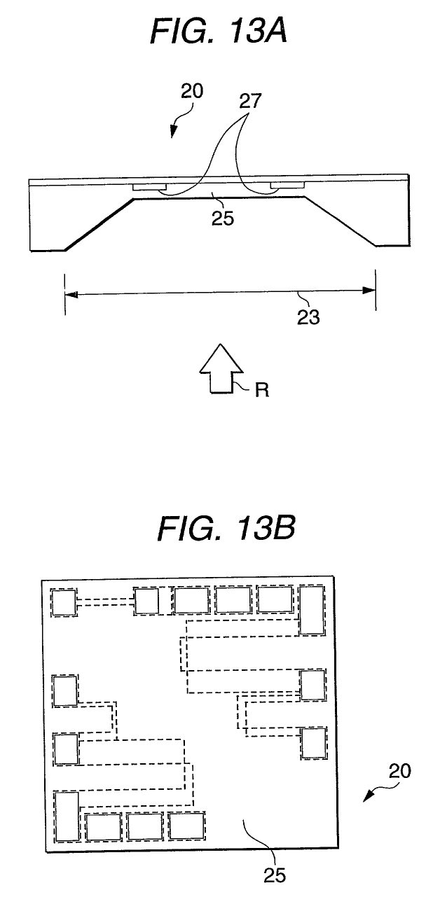

The semiconductor element 20 is, for example, a piezoresistive microphone including piezoelectric resistors 27 as shown in FIG. 13A. This semiconductor element 20 includes a substrate of Si (silicon) and an insulating film of SiO₂, and a sealing inhibited region 23 at its center region. A thin portion 25 is formed in a portion of this sealing inhibited region 23. This thin portion 25 is constructed such that air in the direction of arrow R flows in and strikes so that the thin portion vibrates. This thin portion 25 is a diaphragm portion and includes the plurality of piezoelectric resistors (piezoelectric elements) 27.

In the case where this semiconductor element 20 is used for a microphone, when the user speaks to this semiconductor element 20, air flows in along the R direction and vibrates the thin portion 25, so that resistance values of the respective piezoelectric resistors 27 are changed. The resistance values of the respective piezoelectric resistors 27 are changed so that audio signals are detected.

Reference will be made again to FIG. 1. A punched hole 50 is provided in the circuit substrate 30 and the anisotropic conductive film 40 as the electrical connection sheet. This punched hole 50 corresponds to the sealing inhibited region 23 of the semiconductor element 20, and has an inner dimension substantially corresponding to the size of the region. This punched hole 50 can be formed into a circular shape, a rectangular shape, or a square shape.

A plurality of projection electrodes 29 are provided on the semiconductor element 20.

The projection electrodes 29 are electrically connected to the corresponding electrodes of the wiring electrodes 33 of the circuit substrate 30 through the anisotropic conductive film 40. This anisotropic conductive film 40 functions also as sealing resin to seal the peripheries of the projection electrodes 29.

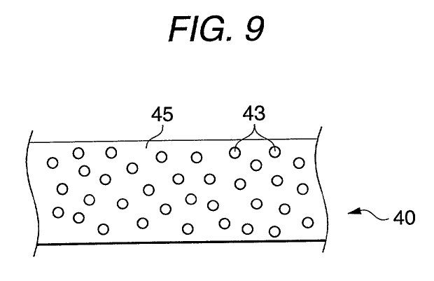

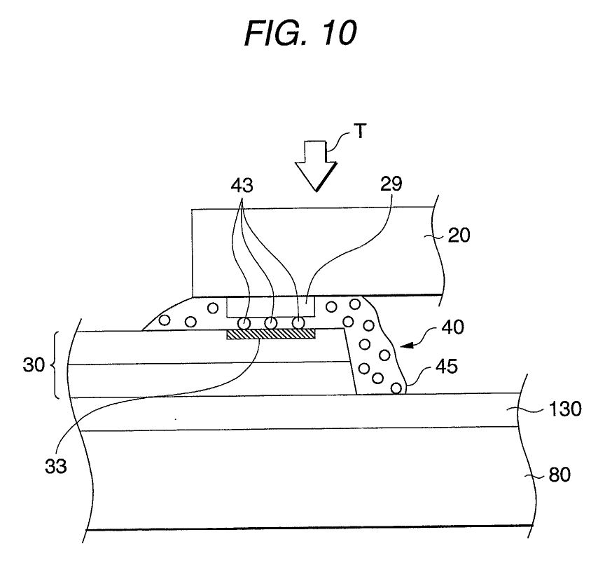

FIGS. 9 and 10 show a structural example of this anisotropic conductive film 40. This anisotropic conductive film 40 is the electrical connection sheet as already described, and includes a number of conductive particles 43 and an electrical insulator 45. The conductive particles 43 are, for example, spherical particles each having, for example, a core material of Ni, core material of Ni+Au plating, core material of epoxy resin+Ni plating+Au plating, or the like. The electrical insulator 45 is made of, for example, epoxy resin, and contains a number of conductive particles 43.

FIG. 10 shows an example in which the projection electrodes 29 of the semiconductor element 20 is electrically connected to the wiring electrodes 33 of the circuit substrate 30 through the plurality of conductive particles 43.

When the semiconductor element 20 is pressed in a T direction, the projection electrodes 29 of the semiconductor element 20 can be electrically connected to the wiring electrodes 33 of the circuit substrate 30 through the plurality of conductive particles 43. The peripheries of the conductive particles 43 are enclosed with the electrical insulator 45, and this electrical insulator 45 functions as sealing resin of the projection electrodes 29 and the wiring electrodes 33.

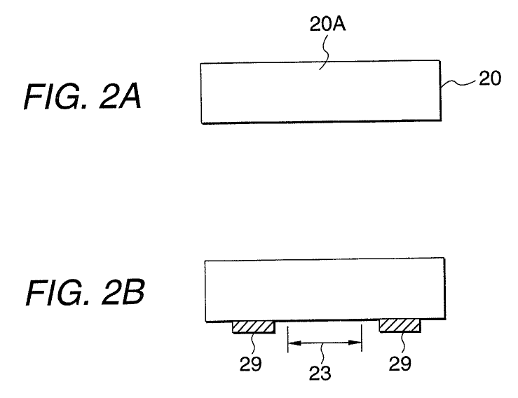

Next, with reference to FIG. 2A to FIG. 8B, a method of manufacturing a semiconductor device 10 of FIG. 1, that is, a connecting method of electrically connecting the semiconductor element 20 to the wiring substrate 30 will be described.

FIGS. 2A and 2B show an example in which a plurality of projection electrodes are formed at predetermined positions to the semiconductor element 20. On a main body 20A of the semiconductor element 20 of FIG. 2A, as shown in FIG. 2B, a plurality of projection electrodes 29 are formed. The projection electrodes 29 are also called bumps, and for example, as a method of forming the bumps, electroless nickel plating is made, and further, Au flash plating is made to form them. The electroless nickel plating has a thickness of, for example, 10 μm, and the Au flash plating has a thickness of 0.04 μm.

The projection electrodes 29 are formed on, for example, aluminum electrodes formed on the main body 20A.

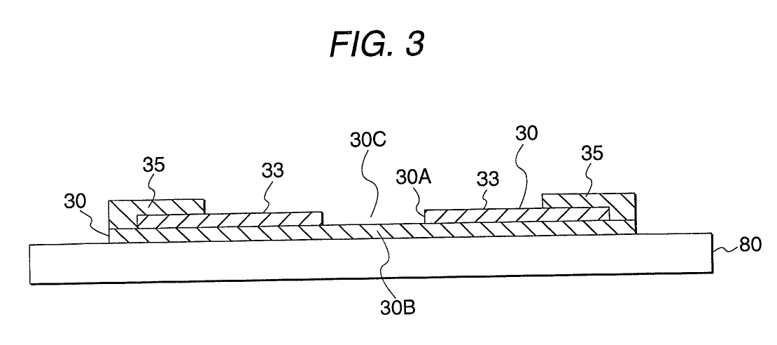

Next, with reference to FIG. 3, the circuit substrate 30 is disposed on a stage 80. On this circuit substrate 30, Cu of lead-out electrode specification is formed to, for example, a thickness of 8 μm by sputtering, nickel is formed to a thickness of 4 μm by plating, and Au is formed to a thickness of 0.02 μm by plating. The solder resist 35 is provided at a predetermined region of this circuit substrate 30.

This circuit substrate 30 includes a first layer (Cu electrode) 30A and a second layer (polyimide) 30B.

The first layer 30A is a Cu electrode, and the second layer 30B is polyimide.

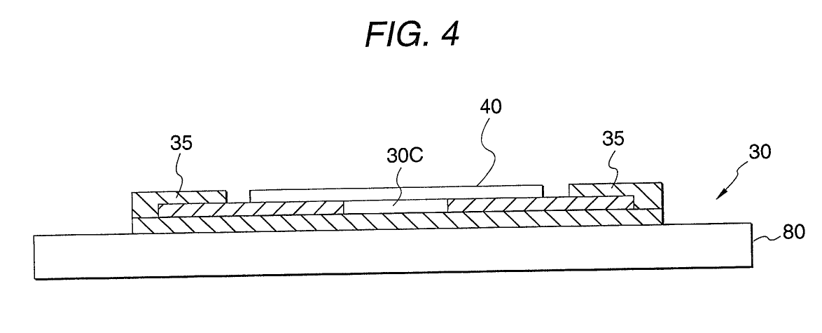

With reference to FIG. 4, as an example of the electrical connection sheet, the anisotropic conductive film 40 is disposed on the circuit substrate 30. As this anisotropic conductive film 40, for example, an anisotropic conductive film (product number FP16613) made by Sony Chemical Co., Ltd. can be used. The thickness of this anisotropic conductive film 40 is, for example, 30 μm, and the anisotropic conductive film 40 is bonded onto the circuit substrate 30.

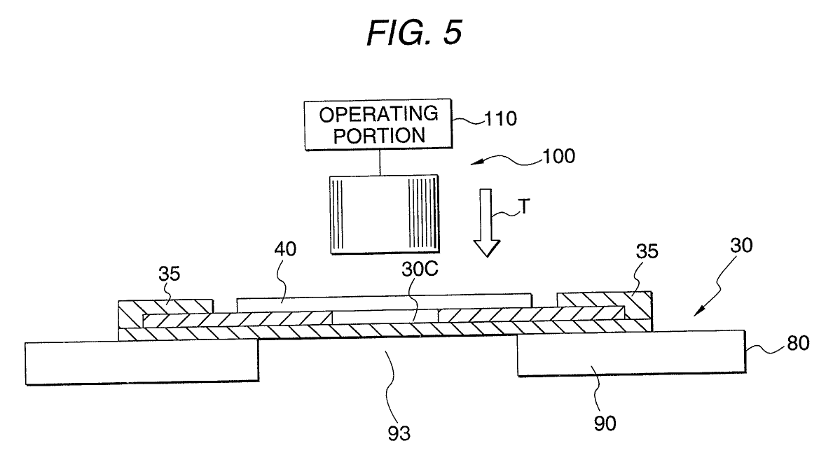

With reference to FIG. 5, a punching head 100 is provided to be movable in a T direction by an operating portion 110. This punching head 100 is a head for punching the anisotropic conductive film 40 and the circuit substrate 30 at the same time along a hole 30C.

In the punching step of FIG. 5, the circuit substrate 30 is put on a stage 90 different from the stage 80 of FIG. 4. A hole 93 is provided at the center of this stage 90. This hole 93 is positioned below the punching head 100, and is sufficiently larger than the size of the punching head 100.

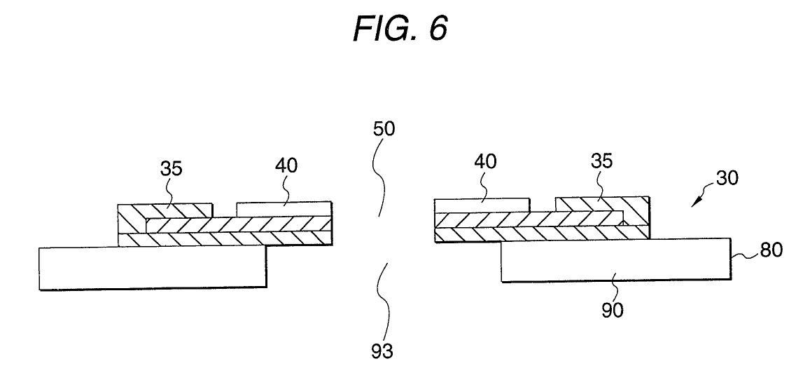

When the punching head 100 of FIG. 5 is lowered in the T direction, as shown in FIG. 6, a punched hole 50 of, for example, a circular shape is formed in the anisotropic conductive film 40 and the circuit substrate 30.

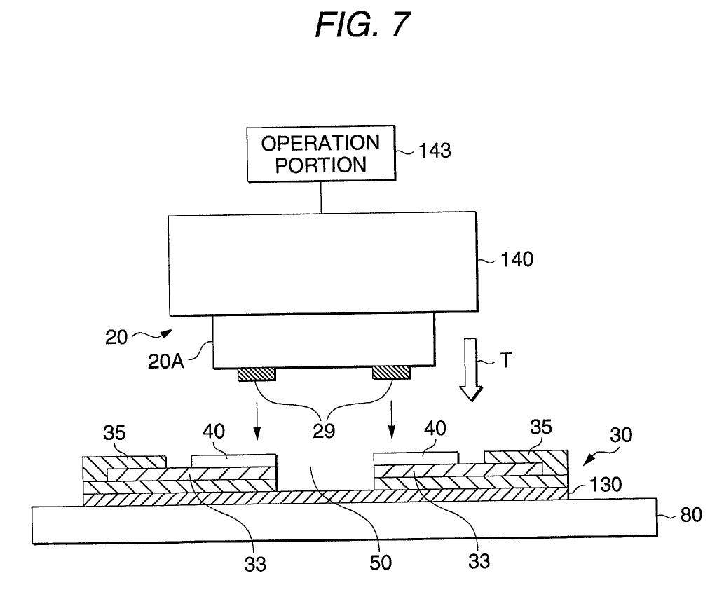

After the punched hole 50 is formed in this way, as shown in FIG. 7, the projection electrodes 29 of the semiconductor element 20 is positioned correspondingly to the corresponding wiring electrodes 33 of the circuit substrate 30.

In this case, the circuit substrate 30 is put on the stage 80, and an adhesion preventing member 130 intervenes between the stage 80 and the circuit substrate 30. This adhesion preventing member 130 is a sheet formed of, for example, polyimide.

A bonding head 140 shown in FIG. 7 can be operated in the T direction by an operating portion 143. This bonding head 140 can heat the main body 20A of the semiconductor element 20 while holding the main body 20A of the semiconductor element 20. Further, by the operation of the operation portion 143 this bonding head 140 has a function of compression bonding the projection electrodes 29 of the semiconductor element 20 to the wiring electrodes 33 of the circuit substrate 30 through the anisotropic conductive film 40 by application of pressure.

The set temperature of the bonding head 140 in this case is, for example, 230° C., and an applicable load is 0.36 Kg. In this case, a load of 60 g is applied to one projection electrode 29. A compression bonding time is, for example, 20 seconds.

The bonding head 140 performs the thermo compression bonding operation by lowering the semiconductor element 20 in the T direction, so that as shown in FIG. 10, the electrical insulator 45 of the anisotropic conductive film 40 is subjected to the thermo compression bonding, and a number of conductive particles 43 electrically connect the projection electrodes 29 to the wiring electrodes 33. Further, the electrical insulator 45 can seal, as a sealing resin, the periphery of the projection electrodes 29 and the wiring electrodes 33.

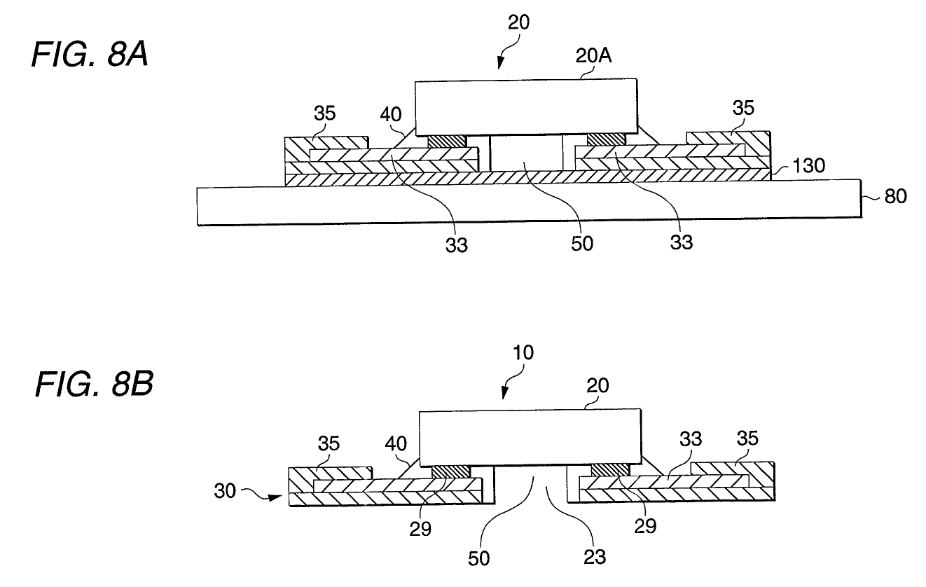

When such a thermo compression bonding operation is ended, the state of FIG. 8A is obtained. At this time, in the thermo compression bonding state shown in FIG. 7 and FIG. 8A, the existence of the adhesion preventing member 130 can prevent the electrical insulator 45 shown in FIG. 10 from protruding and adhering to the lower side of the circuit substrate 30, that is, the stage 80.

As shown in FIG. 8A, when the thermo compression bonding operation of the semiconductor element 20 is ended, as shown in FIG. 8B, the completed semiconductor device 10 is removed from the stage of FIG. 8A, and the adhesion preventing member 130 is removed. In the manner as described above, the semiconductor device 10 shown in FIG. 1 and FIG. 8B is completed.

As shown in FIG. 3, the circuit substrate 30 is the two-layer flexible printed substrate made of the first layer 30A and the second layer 30B. The adoption of the two-layer circuit substrate 30 like this is advantageous as compared with the adoption of, for example, a three-layer circuit substrate in the following point.

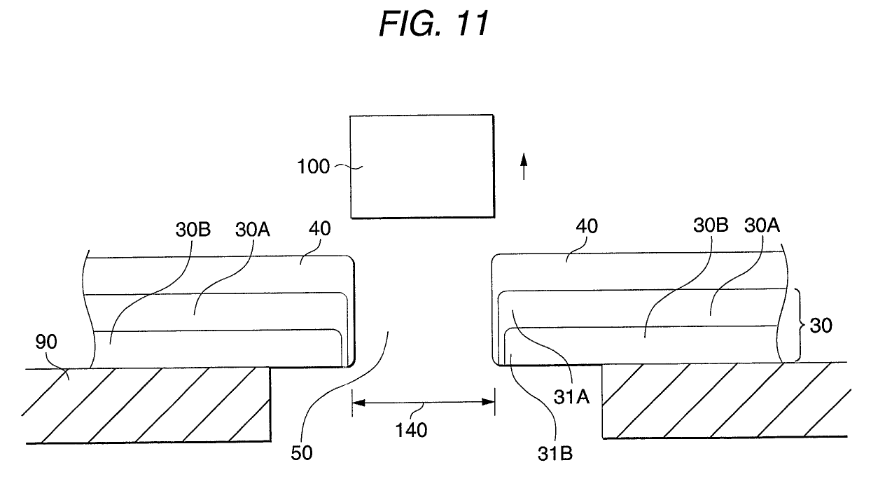

FIG. 11 shows the two-layer circuit substrate 30, and shows the state after the anisotropic conductive film 40 and the circuit substrate 30 are punched by the punching head 100. In this case, drooping portions 31A and 31B by punching are not particularly formed in the first layer 30A and the second layer 30B of the circuit substrate 30. From this, an inner size 140 of the punched hole 120 does not become very small.

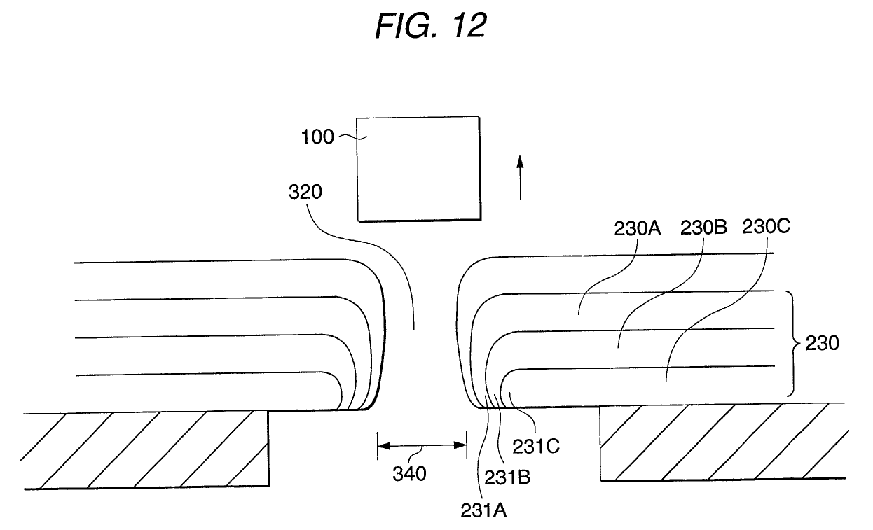

On the other hand, in a comparative example shown in FIG. 12, an example of a three-layer circuit substrate 230 is shown. The three-layer circuit substrate 230 includes a first layer 230A, a second layer 230B, and a third layer 230C, and in the case where they are punched by the punching head 100, drooping portions 231A, 231B and 231C are formed. From this, an inner size 340 of a punched hole 320 becomes considerably small as compared with the inner size 140 shown in FIG. 11. When the inner size 340 becomes small like this, there is a fear that the sealing inhibited region 23 of the semiconductor element 20 shown in FIG. 1 is narrowed. From this, as the circuit substrate 30, it is desirable to use the so-called two-layer flexible wiring substrate or two-layer printed wiring substrate.

In the embodiment of the present invention, the projection electrodes of the semiconductor element are electrically connected to the wiring portions of the circuit substrate through the electrical connection sheet such as the anisotropic conductive sheet or resin sheet. In the case of the semiconductor element including the sealing inhibited region in which adhering and sealing of resin are inhibited, the portions of the circuit substrate and the electrical connection sheet bonded to its upper surface, which correspond to the sealing inhibited region, are simultaneously removed by punching. Only the projection electrodes on the periphery of the semiconductor element and the wiring portions of the circuit substrate are electrically connected to each other by use of the electrical connection sheet.

The semiconductor element is a device, for example, a charge coupled element or an element including a piezoelectric resistor, in which its center portion can not be sealed by resin.

The projection electrodes of the semiconductor element can be made of plating such as electroless nickel plating+ Au flash plating, Au plating, or Cu+Au flash plating, or wire such as Au or Al.

The substrate is, for example, a flexible wiring substrate or a thin printed wiring substrate, which can be punched at the same time as the electrical connection sheet.

When electrical connection is made, at the time of compression bonding of the semiconductor element, since resin of the anisotropic conductive sheet or resin sheet protrudes from the punched hole and adheres to the stage, the adhesion preventing sheet made of polyimide, Teflon or the like is bonded to the substrate after punching.

Although the projection electrodes of the semiconductor element were formed by electroless nickel plating here, Au plating, Cu plating, or Au stud bump may be used.

As described above, according to the present invention, even in the case where a semiconductor element includes a sealing inhibited region, it can be easily electrically connected to a substrate, and thinning and miniaturization can be realized.

What is claimed is:

1. A connecting method of a semiconductor element, for electrically connecting a semiconductor element to a substrate, comprising the steps of:
disposing an electrical connection sheet on the substrate, for enabling electrical connection between the semiconductor element and the substrate;
forming a punched hole by punching a region of the substrate corresponding to a sealing inhibited region of the semiconductor element which is a region where a function of the semiconductor element is performed and sealing is inhibited, together with the electrical connection sheet;
disposing the semiconductor element on the substrate through the electrical connection sheet; and
electrically connecting electrodes located at a remainder portion except the sealing inhibited region of the semiconductor element to electrodes of the substrate.

2. The connecting method of the semiconductor element according to claim 1, wherein the semiconductor element is one selected from the group consisting of a piezoelectric element and a charge coupled element.

3. The connecting method of the semiconductor element according to claim 1, wherein the electrodes of the substrate are connected to projection electrodes of the semiconductor element through the electrical connection sheet.

4. The connecting method of the semiconductor element according to claim 3, wherein the electrical connection sheet is made of a plurality of conductive particles and an electrical insulator containing the conductive particles.

5. The connecting method of the semiconductor element according to claim 1, wherein the substrate is one selected from the group consisting of a printed wiring substrate and a flexible wiring substrate.

6. The connecting method of the semiconductor element according to claim 1, wherein the electrical connection sheet and the region of the substrate corresponding to the sealing inhibited region are punched simultaneously and from an electrical connection sheet side to form the punched hole.

7. The connecting method of the semiconductor element according to claim 1, wherein an adhesion preventing member is disposed to prevent a part of the electrical connection sheet from protruding through the punched hole to an opposite side of the substrate and adhering when the semiconductor element is disposed on the substrate through the electrical connection sheet, and the electrodes located at the remainder portion except the sealing inhibited region of the semiconductor element is electrically connected to the electrode of the substrate.

8. The connecting method of the semiconductor element according to claim 1, wherein in a case where the substrate is a flexible wiring substrate, the substrate is a two-layer substrate.

9. A semiconductor device comprising:
a semiconductor element including a sealing inhibited region which is a region where a function is performed and sealing is inhibited;
a substrate; and
an electrical connection sheet disposed on the substrate and enabling electrical connection between the semiconductor element and the substrate, a punched hole being formed in the electrical connection sheet by punching it together with a region of the substrate corresponding to the sealing inhibited region of the semiconductor element,
wherein the semiconductor element is disposed on the substrate through the electrical connection sheet, and electrodes located at a remainder portion except the sealing inhibited region of the semiconductor element is electrically connected to electrodes of the substrate.

10. The semiconductor device according claim 9, wherein the semiconductor element is one selected from the group consisting of a piezoelectric element and a charge coupled element.

11. The semiconductor device according to claim 9, wherein the electrodes of the substrate is connected to projection electrodes of the semiconductor element through the electrical connection sheet.

12. The semiconductor device according to claim 9, wherein the electrical connection sheet is made of a plurality of conductive particles and an electrical insulator containing the conductive particles.

13. The semiconductor device according to claim 9, wherein the substrate is one selected from the group consisting of a printed wiring substrate and a flexible wiring substrate.

14. The semiconductor device according to claim 9, wherein the electrical connection sheet and the region of the substrate corresponding to the sealing inhibited region are punched simultaneously and from an electrical connection sheet side to form the punched hole.
